(19) United States
(12) Patent Application Publication
(10) Pub. No.: US 2023/0170191 A1
(43) Pub. Date: Jun. 1, 2023

(54) WAFER PLACEMENT TABLE

(71) Applicant: NGK Insulators, Ltd., Nagoya-City (JP)

(72) Inventors: Seiya INOUE, Handa-City (JP); Tatsuya KUNO, Nagoya-City (JP); Ikuhisa MORIOKA, Handa-City (JP)

(73) Assignee: NGK Insulators, Ltd., Nagoya-City (JP)

(21) Appl. No.: 17/931,916

(22) Filed: Sep. 14, 2022

(30) Foreign Application Priority Data
Nov. 29, 2021 (JP) 2021-192899

(51) Int. Cl. H01J 37/32; H01L 21/683

(52) U.S. Cl. CPC H01J 37/32724; H01L 21/6833; H01J 2237/002; H01J 2237/2007

(57) ABSTRACT

A wafer placement table has a wafer placement surface that allows a wafer to be placed thereon. The wafer placement table includes a ceramic substrate having a built-in electrode, a cooling substrate including a refrigerant flow path, a metal joining layer that joins the ceramic substrate to the cooling substrate, and a plurality of small protrusions disposed on a reference plane of the wafer placement surface. The top surfaces of the small protrusions can support the lower surface of a wafer. The top surfaces of all the small protrusions are located on the same plane. In a flow path overlapping range of the wafer placement surface in which the wafer placement surface overlaps the refrigerant flow path in plan view, an area ratio of the small protrusions is minimized in a portion facing a most upstream portion of the refrigerant flow path.

### BACKGROUND OF THE INVENTION

### 1. Field of the Invention

The present invention relates to a wafer placement table.

### 2. Description of the Related Art

A wafer placement table has been developed that includes a ceramic substrate having a wafer placement surface and a built-in electrode, a cooling substrate having a refrigerant flow path, and a joining layer for joining the ceramic substrate to the cooling substrate. For example, PTLs 1 and 2 describe a wafer placement table including a cooling substrate made of a metal matrix composite having a linear thermal expansion coefficient similar to that of a ceramic substrate. In addition, PTLs 1 and 2 describe that a terminal hole, a gas hole, and a lift pin hole are provided in the wafer placement table. The terminal hole is used to insert a feeding terminal for supplying power to the electrode, the gas hole is used to supply He gas to the back surface of the wafer, and the lift pin hole is used to insert a lift pin for lifting the wafer from the wafer placement surface.

### CITATION LIST

### Patent Literature

PTL 1: Japanese Patent No. 5666748 B

PTL 2: Japanese Patent No. 5666749 B

### SUMMARY OF THE INVENTION

However, when the wafer placement table is used, the refrigerant flows from the upstream to the downstream of the refrigerant flow path while taking heat from the wafer, so that the temperature of the refrigerant tends to be higher on the downstream side than on the upstream side. As a result, it is difficult to obtain a sufficient thermal uniformity of the wafer in some cases.

The present invention is made to solve such an inconvenience, it is a primary object of the present invention to improve the thermal uniformity of a wafer.

A first wafer placement table according to the present invention includes a ceramic substrate having an upper surface serving as a wafer placement surface that allows a wafer to be placed thereon, where the ceramic substrate has a built-in electrode, a cooling substrate including a refrigerant flow path, a joining layer configured to join the ceramic substrate to the cooling substrate, and a plurality of small protrusions disposed on a reference plane of the wafer placement surface, where top surfaces of the small protrusions support a lower surface of the wafer. The top surfaces of all the small protrusions are located on the same plane. In a flow path overlapping range of the wafer placement surface in which the wafer placement surface overlaps the refrigerant flow path in plan view, the area ratio of the small protrusions is minimized in a portion facing a most upstream portion of the refrigerant flow path within a range in which the refrigerant flow path overlaps the wafer placement surface in plan view.

In the first wafer placement table, the area ratio of the small protrusions in the flow path overlapping range is minimized in the portion facing the most upstream portion. As used herein, the term “area ratio of small protrusions” refers to the ratio of the total area of small protrusions to a unit area. When the wafer placement table is used, the refrigerant flows from the upstream to the downstream of the refrigerant flow path while taking heat from the high-temperature wafer. For this reason, the temperature of the refrigerant flowing through the refrigerant flow path is higher on the downstream side than on the upstream side. In contrast, in the wafer placement table, the area ratio of the small protrusions in the flow path overlapping range is minimized in the portion facing the most upstream portion. For this reason, the thermal resistance from the refrigerant flow path to the wafer placement surface is lower in a portion not facing the most upstream portion than in the portion facing the most upstream portion. This is due to the following reason: The small protrusions are made of ceramic, and ceramic has higher thermal conductivity than a void. Therefore, in the portion where the area ratio of the small protrusions is high, the proportion of the ceramic in the planar direction is higher than in the portion where the area ratio of the small protrusion is not high and, thus, heat exchange between the wafer and the refrigerant is promoted. As a result, removal of Heat is promoted. Therefore, on the whole, the temperature difference can be reduced within the flow path overlapping range of the wafer placement surface, which increases the thermal uniformity of the wafer.

According to the first wafer placement table of the present invention, the area ratio of the small protrusions in the flow path overlapping range may gradually increase toward a downstream of the refrigerant flow path from the portion facing the most upstream portion. In this way, the thermal uniformity of the wafer is increased more.

According to the first wafer placement table of the present invention, in the flow path overlapping range, the area ratio of the small protrusions in a portion facing a most downstream portion of the refrigerant flow path within a range in which the refrigerant flow path overlaps the wafer placement surface in plan view may be greater than or equal to 150% of the area ratio of the small protrusions in the portion facing the most upstream portion. In this way, the thermal uniformity of the wafer is increased more.

According to the first wafer placement table of the present invention, in terms of a predetermined region in the flow path overlapping range, the area ratio of the small protrusions may be higher in an adjacent region adjacent to the predetermined region and outside the flow path overlapping range than in the predetermined region. In general, heat is less likely to be removed from the adjacent region than from the predetermined region within the flow path overlapping range. This is because the refrigerant flow path is not located directly below the adjacent region. In contrast, according to the wafer placement table, the area ratio of the small protrusions is higher in the adjacent region than in the predetermined region in the flow path overlapping range. For this reason, heat removal from the predetermined region is promoted. As a result, the thermal uniformity of the wafer is increased more.

The first wafer placement table of the present invention may include a hole configured to penetrate the cooling substrate in the vertical direction. The cross-sectional area of the refrigerant flow path may be less in a surrounding region of the hole than in a region outside the surrounding region of the hole, and the area ratio of the small protrusions may be higher in a directly above region of the wafer placement surface that is located directly above the hole than in a region outside the directly above region. In general, a portion of the wafer in the region directly above the hole is likely to be a hot spot. However, the area ratio of the small protrusions is higher in the directly above region than in the surrounding region. For this reason, heat removal from the directly above region is promoted. As a result, the thermal uniformity of the wafer is increased more.

A second wafer placement table of the present invention includes a ceramic substrate having an upper surface serving as a wafer placement surface that allows a wafer to be placed thereon, where the ceramic substrate has a built-in electrode, a cooling substrate including a refrigerant flow path, a joining layer configured to join the ceramic substrate to the cooling substrate, and a plurality of small protrusions disposed on a reference plane of the wafer placement surface, where top surfaces of the small protrusions support a lower surface of the wafer. The top surfaces of all the small protrusions are located on the same plane. The top surfaces of all the small protrusions are located on the same plane. In a flow path overlapping range of the wafer placement surface in which the wafer placement surface overlaps the refrigerant flow path in plan view, a distance from the top surface of the small protrusion to the reference plane is maximized in a portion facing a most upstream portion of the refrigerant flow path within a range in which the refrigerant flow path overlaps the wafer placement surface in plan view.

According to the second wafer placement table, the distance from the top surface of the small protrusion to the reference plane in the flow path overlapping range is maximized in the portion facing the most upstream portion. When the wafer placement table is used, the refrigerant flows from the upstream to the downstream of the refrigerant flow path while taking heat from the high-temperature wafer. For this reason, the temperature of the refrigerant flowing through the refrigerant flow path is higher on the downstream side than on the upstream side. In contrast, according to the wafer placement table, since the distance from the top surface of the small protrusion to the reference plane in the flow path overlapping range is maximized in the portion facing the most upstream portion, the thermal resistance from the refrigerant flow path to the wafer placement surface is lower in a portion other than the portion facing the most upstream portion than in the portion facing the most upstream portion. This is due to the following reason: The small protrusions are made of ceramic, and ceramic has better thermal conductivity than a void. Therefore, the proportion of void in the thickness direction is lower in a portion in which the distance from the small protrusion to the reference plane is short than in a portion in which the distance from the small protrusion to the reference plane is not short. As a result, heat exchange between the wafer and the refrigerant is promoted, and removal of heat is promoted. Therefore, on the whole, the temperature difference can be reduced within the flow path overlapping range of the wafer placement surface, which increases the thermal uniformity of the wafer.

According to the second wafer placement table of the present invention, the distance from the top surface of the small protrusion to the reference plane in the flow path overlapping range gradually may decrease toward a downstream of the refrigerant flow path from the portion facing the most upstream portion. In this way, the thermal uniformity of the wafer is increased more.

According to the second wafer placement table of the present invention, in the flow path overlapping range viewed in plan, the distance from the top surface of the small protrusion to the reference plane in the portion facing the most downstream portion of the refrigerant flow path within a range in which the refrigerant flow path overlaps the wafer placement surface in plan view may be less than or equal to 80% of the distance from the top surface of the small protrusion to the reference plane in the portion facing the most upstream portion. In this way, the thermal uniformity of the wafer is increased more.

According to the second wafer placement table of the present invention, in terms of a predetermined region in the flow path overlapping range, the distance from the top surface of the small protrusion to the reference plane may be less in an adjacent region adjacent to the predetermined region and outside the flow path overlapping range than in the predetermined region. In general, heat is less likely to be removed from the adjacent region than from the predetermined region of the flow path overlapping range. This is because there is no refrigerant flow path directly below. In contrast, according to the wafer placement table of the present invention, the distance from the top surface of the small protrusion to the reference plane is less in the adjacent region than in the predetermined region of the flow path overlapping range. Therefore, heat removal in the predetermined range is promoted. As a result, the thermal uniformity of the wafer is increased more.

The second wafer placement table of the present invention may include a hole configured to penetrate the cooling substrate in the vertical direction. The cross-sectional area of the refrigerant flow path may be less in a surrounding region of the hole than in a region outside the surrounding region of the hole, and the distance from the top surface of the small protrusion to the reference plane may be less in the surrounding region of the hole than in the surrounding region outside a region directly above the hole in the wafer placement surface. In general, a portion of the wafer in the region directly above the hole is likely to be a hot spot. However, the distance from the small protrusion to the reference plane is less in the directly above region than in the surrounding region. For this reason, heat removal from the directly above region is promoted. As a result, the thermal uniformity of the wafer is increased more.

According to the first and second wafer placement tables of the present invention, the cooling substrate may be made of a metal matrix composite, and the joining layer may be a metal joining layer. In a structure in which the cooling substrate is a metal matrix composite and the joining layer is a metal joining layer, the thermal resistance from the refrigerant flow path to the wafer placement surface is small, so that the wafer temperature is easily influenced by the temperature gradient of the refrigerant. Therefore, it is highly effective to apply the present invention. Furthermore, since the metal joining layer has high thermal conductivity, it is suitable for heat removal. Still furthermore, since the difference in thermal expansion between the ceramic substrate and the cooling substrate made of the metal matrix composite can be reduced, no problem is likely to occur even if the stress relaxation property of the metal joining layer is low.

### BRIEF DESCRIPTION OF THE DRAWINGS

FIG. 1 is a vertical sectional view of a wafer placement table 10 mounted in a chamber 94.

FIG. 2 is a plan view of the wafer placement table 10.

FIG. 3 is a cross-sectional view of a cooling substrate 30 cut by a horizontal plane passing through a refrigerant flow path 32, viewed from above.

FIG. 4 is an enlarged view of a small region Ai and an adjacent region Qi.

FIG. 5 is a block diagram of a directly above region R30 and a surrounding region R40.

FIGS. 6A to 6G are manufacturing process diagrams of the wafer placement table 10.

FIG. 7 illustrates the distance from the top surface of a small protrusion 22c to a reference plane 22d in each of small regions A1 and Ak.

FIG. 8 is a plan view of another example of the wafer placement table 10.

FIG. 9 is a cross-sectional view of the cooling substrate 30 as viewed from above when the cooling substrate 30 is cut by the horizontal plane passing through a refrigerant flow path 82.

FIG. 10 is a plan view of still another example of the wafer placement table 10.

### DETAILED DESCRIPTION OF THE INVENTION

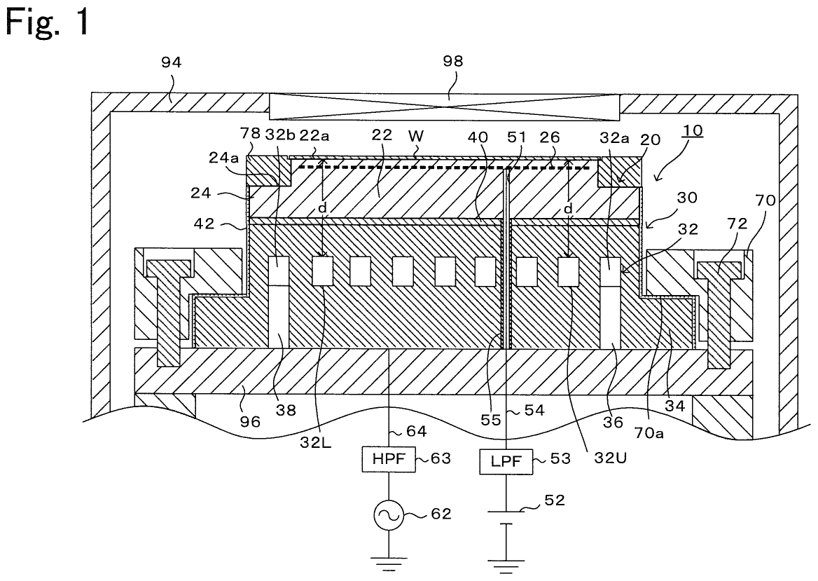

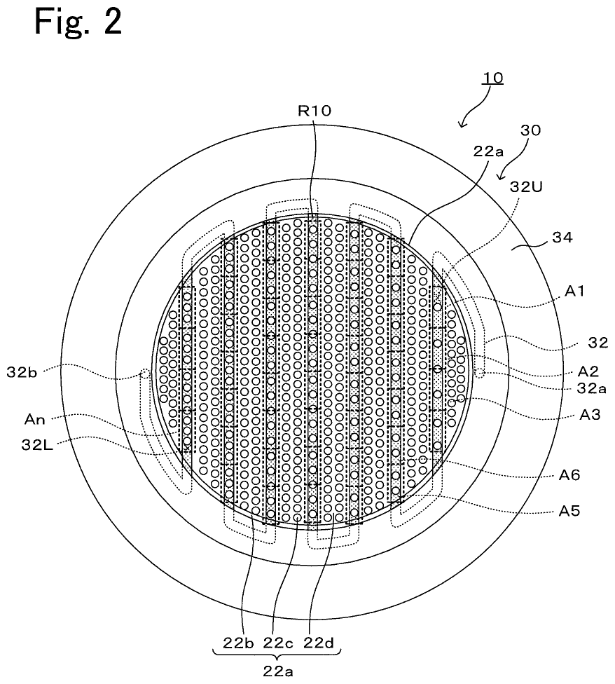

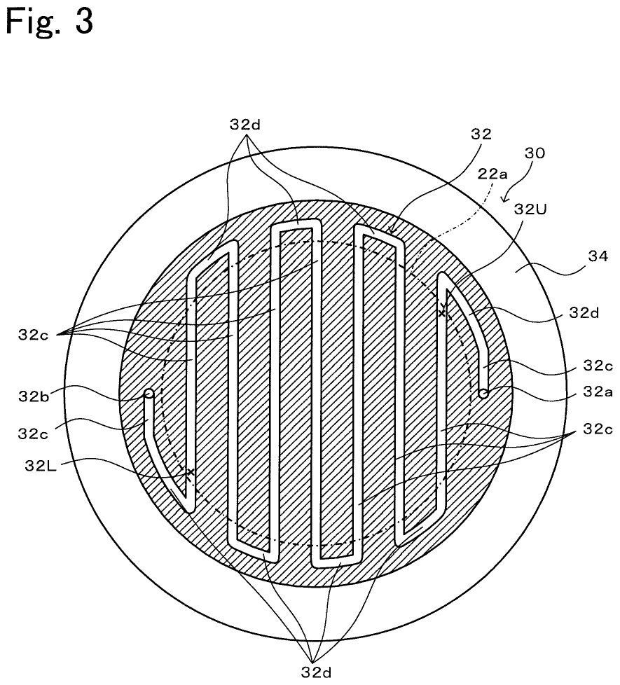

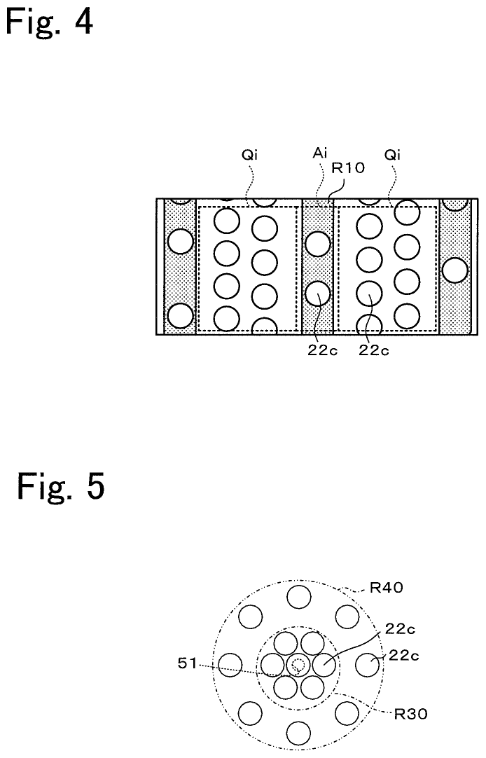

Exemplary embodiments of the present invention are described below with reference the accompanying drawings. FIG. 1 is a vertical sectional view of a wafer placement table 10 mounted in a chamber 94 (a cross-sectional view when cut in a plane including the central axis of the wafer placement table 10), FIG. 2 is a plan view of the wafer placement table 10, FIG. 3 is a cross-sectional view of the cooling substrate 30 viewed from above when the cooling substrate 30 is cut in a horizontal plane passing through the refrigerant flow path 32, FIG. 4 is an enlarged view of a small region Ai and an adjacent region Qi, and FIG. 5 is a directly above region R30 and a surrounding region R40. Note that for convenience of description, in FIGS. 2 and 4, a flow path overlapping range R10 is hatched. In addition, in FIG. 3, a terminal hole 51, a feeding terminal 54, an insulating tube 55, and the like are not illustrated.

The wafer placement table 10 is used for performing CVD, etching, or the like on a wafer W by using plasma. The wafer placement table 10 is fixed to an installation plate 96 provided inside the chamber 94 for a semiconductor process. The wafer placement table 10 includes a ceramic substrate 20, the cooling substrate 30, and a metal joining layer 40.

The ceramic substrate 20 includes an outer peripheral portion 24 having an annular focus ring placement surface 24a on the outer periphery of a central portion 22 having a circular wafer placement surface 22a. Hereinafter, the focus ring is also simply referred to as FR. The wafer W is placed on the wafer placement surface 22a, and a focus ring 78 is placed on the FR placement surface 24a. The ceramic substrate 20 is made of a ceramic material (typically, alumina or aluminum nitride). The FR placement surface 24a is one step lower than the wafer placement surface 22a.

The central portion 22 of the ceramic substrate 20 incorporates a wafer suction electrode 26 so that the wafer suction electrode 26 is adjacent to the wafer placement surface 22a. The wafer suction electrode 26 is formed of a material containing, for example, W, Mo, WC, MoC, or the like. The wafer suction electrode 26 is a disk-shaped or mesh-shaped unipolar electrostatic suction electrode. A layer of the ceramic substrate 20 higher than the wafer suction electrode 26 functions as a dielectric layer. A wafer suction DC power supply 52 is connected to the wafer suction electrode 26 via the feeding terminal 54. The feeding terminal 54 is inserted into the terminal hole 51 provided between the lower surface of the wafer suction electrode 26 and the lower surface of the cooling substrate 30 of the wafer placement table 10. The feeding terminal 54 extends through an insulating tube 55 disposed in a through-hole of the terminal hole 51 that penetrates the cooling substrate 30 and the metal joining layer 40 in the vertical direction and reaches the wafer suction electrode 26 from the lower surface of the ceramic substrate 20. A lowpass filter (LPF) 53 is provided between the wafer suction DC power supply 52 and the wafer suction electrode 26.

As illustrated in FIG. 2, a seal band 22b is formed on the wafer placement surface 22a along the outer edge, and a plurality of small protrusions 22c are formed across the entire surface of the wafer placement surface 22a. The seal band 22b and the plurality of small protrusions 22c are formed on a reference plane 22d of the wafer placement surface 22a. According to the present embodiment, each of the small protrusion 22c is a flat cylindrical protrusion. The top surface of the seal band 22b and the top surfaces of all the small protrusions 22c are located on the same plane. The heights of the seal band 22b and the small protrusions 22c (that is, the distance from the reference plane 22d to the top surfaces) are several pm to several tens of μm. The wafer W is placed on the wafer placement surface 22a so as to be in contact with the top surface of the seal band 22b and the top surfaces of the plurality of small protrusions 22c.

The cooling substrate 30 is a disk member made of a metal matrix composite (also referred to as MMC). The cooling substrate 30 has a refrigerant flow path 32 thereinside. The refrigerant flow path 32 allows a refrigerant to circulate therein. The refrigerant flow path 32 is connected to a refrigerant supply path 36 and a refrigerant discharge path 38. The refrigerant discharged from the refrigerant discharge path 38 is temperature-regulated and, thereafter, is returned to the refrigerant supply path 36 again. Examples of the MMC include a material containing Si, SiC and Ti and a material obtained by impregnating an SiC porous body with Al and/or Si. The material containing Si, SiC and Ti is referred to as SiSiCTi, the material obtained by impregnating a SiC porous body with Al is referred to as AlSiC, and the material obtained by impregnating a SiC porous body with Si is referred to as SiSiC. When the ceramic substrate 20 is an alumina substrate, it is desirable that the MMC used for the cooling substrate 30 be AlSiC or SiSiCTi having a thermal expansion coefficient close to that of alumina. The cooling substrate 30 is connected to an RF power supply 62 via the feeding terminal 64. A high-pass filter (HPF) 63 is disposed between the cooling substrate 30 and the RF power supply 62. The cooling substrate 30 has a flange portion 34 on the lower surface thereof. The flange portion 34 is used to clamp the wafer placement table 10 to the installation plate 96.

As illustrated in FIG. 3, the refrigerant flow path 32 is formed so as to, when the cross section of the refrigerant flow path 32 obtained by cutting the refrigerant flow path 32 in a horizontal plane is viewed from above, meander in a one-stroke pattern from an inlet 32a to an outlet 32b across the entire region of the cooling substrate 30 excluding the flange portion 34. According to the present embodiment, the refrigerant flow path 32 is formed in a zigzag pattern. More specifically, the refrigerant flow path 32 has linear portions 32c and folded portions 32d alternately so as to meander from the inlet 32a connected to the refrigerant supply path 36 to the outlet 32b connected to the refrigerant discharge path 38. Note that when, in a region of the refrigerant flow path 32 overlapping the wafer placement surface 22a in plan view, a most upstream portion 32U and a most downstream portion 32L of the refrigerant flow path 32 are defined, the most upstream portion 32U and the most downstream portion 32L are located as illustrated in FIG. 3. The cross-sectional area of the refrigerant flow path 32 gradually increases from the most upstream portion 32U toward the most downstream portion 32L of the refrigerant flow path 32, except for that in the surrounding region of the terminal hole 51. As illustrated in FIG. 1, a distance d from a ceiling surface of the refrigerant flow path 32 to the top surface of the small protrusion 22c provided on the wafer placement surface 22a is constant between the most upstream portion 32U and the most downstream portion 32L.

The metal joining layer 40 joins the lower surface of the ceramic substrate 20 to the upper surface of the cooling substrate 30. The metal joining layer 40 may be a layer formed of, for example, solder or a metal brazing material. The metal joining layer 40 is formed by, for example, TCB (Thermal compression bonding). The TCB is an existing technique of sandwiching a metal joining material between two members to be joined and pressure-joining the two members together while heating the metal joining material and the two members to a temperature lower than or equal to the solidus temperature of the metal joining material.

The range of the wafer placement surface 22a that overlaps the refrigerant flow path 32 in plan view is referred to as a “flow path overlapping range R10”. The flow path overlapping range R10 is the hatched area in FIG. 2. The area ratio of the small protrusions 22c to the flow path overlapping range R10 is defined as the ratio of the total area of the top surfaces of the small protrusions 22c in a unit area to the unit area and is obtained as follows. That is, as illustrated in FIG. 2, the flow path overlapping range R10 is divided into n regions (n is an integer greater than or equal to 2) first. At this time, among the n regions, the i-th region (i is an integer greater than or equal to 1 and less than or equal to n) from the upstream of the refrigerant flow path 32 is referred to as a “small region Ai”., The areas of the small regions A1 to An are all the same. Subsequently, the area of the small region Ai is obtained, and the total area of the top surfaces of the small protrusions 22c disposed in the small region Ai is obtained. Then, the total area of the small protrusions 22c in the small region Ai is divided by the area of the small region Ai to obtain the area ratio of the small protrusions 22c in the small region Ai. The area ratio of the small protrusions 22c in the flow path overlapping range R10 is minimized in a portion facing the most upstream portion 32U, that is, the small region A1.

The area ratio of the small protrusions 22c in the flow path overlapping range R10 gradually increases from the small region A1 toward the downstream of the refrigerant flow path 32 (from the small region A1 toward the small region An). The small region An is a portion facing the most downstream portion 32L. It is desirable that the area ratio of the small protrusions 22c in the small region An of the flow path overlapping range R10 facing the most downstream portion 32L be greater than or equal to 150% of the area ratio of the small protrusions 22c in the small region A1 facing the most upstream portion 32U.

The area ratio of the small protrusions 22c is higher in the adjacent region Qi that is adjacent to the small region Ai and outside the flow path overlapping range R10 than in the small region Ai of the flow path overlapping range R10. For example, as illustrated in FIG. 4, the area ratios of the small protrusions 22c in the adjacent regions Qi on either side of the small region Ai (for example, the small region A6) are higher than the area ratio of the small protrusions 22c in the small region Ai.

Let R30 denote a region of the wafer placement surface 22a directly above the terminal hole 51, and let R40 denote the surrounding region that surrounds the directly above region R30 and that is outside the directly above region R30. The directly above region R30 is a circular region having a predetermined radius (for example, a radius of 25 mm), and the surrounding region R40 is an annular region surrounding the directly above region R30. The area ratio of the small protrusions 22c is higher in the directly above region R30 than in the surrounding region R40. For example, as illustrated in FIG. 5, the small protrusions 22c are provided such that the array density of the small protrusions 22c is higher in the directly above region R30 than in the surrounding region R40. It is desirable that the area ratio of the small protrusions 22c in the directly above region R30 be greater than or equal to twice the area ratio of the small protrusions 22c in the surrounding region R40.

The side surface of the outer peripheral portion 24 of the ceramic substrate 20, the outer periphery of the metal joining layer 40, and the side surface of the cooling substrate 30 are covered by an insulating film 42. An example of the insulating film 42 is a thermal spraying film, such as an alumina or yttria thermal spraying film.

The wafer placement table 10 described above is attached to an installation plate 96 provided inside the chamber 94 by using a clamp member 70. The clamp member 70 is an annular member having a substantially inverted L-shaped cross section and having a stepped inner side surface 70a. The wafer placement table 10 and the installation plate 96 are integrated by the clamp member 70. The stepped inner side surface 70a of the clamp member 70 is stacked on the flange portion 34 of the cooling substrate 30 of the wafer placement table 10, and a bolt 72 is inserted from the upper surface of the clamp member 70 and is screwed into a screw hole formed on the upper surface of the installation plate 96. The bolts 72 are screwed at a plurality of locations (for example, 8 or 12 locations) provided at equal intervals along the circumferential direction of the clamp member 70. The clamp member 70 and the bolts 72 may be made of an insulating material or a conductive material (for example, metal).

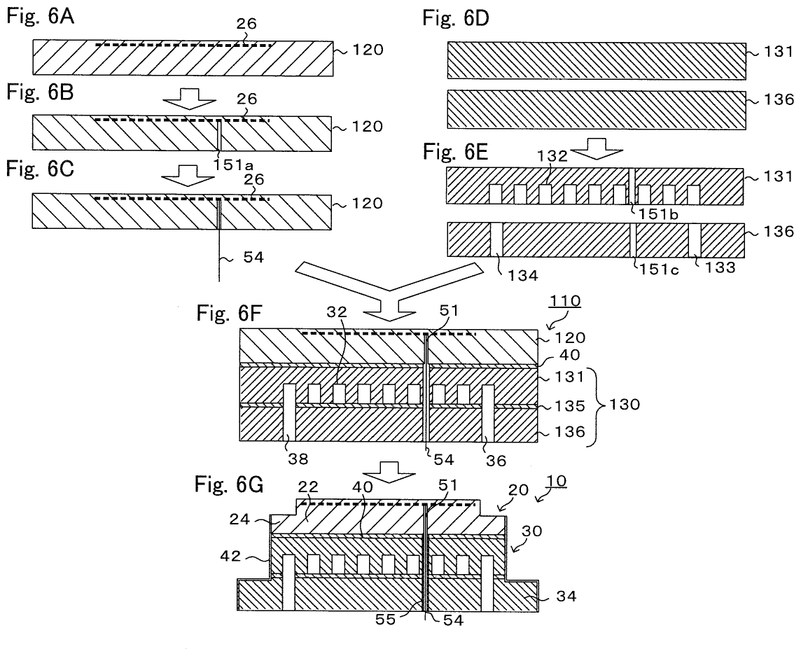

An example of manufacturing the wafer placement table 10 is described below with reference to FIGS. 6A to 6G. FIGS. 6A to 6G are a manufacturing process diagrams of the wafer placement table 10. A disk-shaped ceramic sintered compact 120, from which the ceramic substrate 20 is to be produced, is made by hot-press firing a ceramic powder molded body first (FIG. 6A). The ceramic sintered compact 120 has a built-in wafer suction electrode 26.

Subsequently, a terminal hole upper portion 151a is formed so as to extend between the lower surface of the ceramic sintered compact 120 and the wafer suction electrode 26 (FIG. 6B). Thereafter, the feeding terminal 54 is inserted into the terminal hole upper portion 151a to join the feeding terminal 54 to the wafer suction electrode 26 (FIG. 6C).

At the same time, two MMC disk members 131 and 136 are produced (FIG. 6D). Thereafter, holes are formed in the two MMC disk members 131 and 136 in the vertical direction, and a groove 132 that finally functions as a refrigerant flow path 32 is formed on the lower surface of the upper MMC disk member 131 (FIG. 6E). More specifically, a terminal hole intermediate portion 151b is formed in the upper MMC disk member 131. The groove 132 is formed by machining the upper MMC disk member 131 so as to have the same shape as the refrigerant flow path 32. In addition, a terminal hole lower portion 151c, a through-hole 133 for the refrigerant supply path, and a through-hole 134 for the refrigerant discharge path are formed in the lower MMC disk member 136. If the ceramic sintered compact 120 is made of alumina, it is desirable that the MMC disk members 131 and 136 be made of SiSiCTi or AlSiC. This is because the coefficient of thermal expansion of alumina is almost the same as the coefficient of thermal expansion of each of SiSiCTi and AlSiC.

The disk member made of SiSiCTi can be produced as described below, for example. Silicon carbide, metallic Si, and metallic Ti are mixed to produce a powder mixture first. Subsequently, a disk-shaped molded body is produced from the obtained powder mixture by uniaxial pressing, and the molded body is hot-press sintered in an inert atmosphere to obtain a disk member made of SiSiCTi.

Subsequently, a metal joining material is disposed between the lower surface of the upper MMC disk member 131 and the upper surface of the lower MMC disk member 136. In addition, a metal joining material is disposed on the upper surface of the upper MMC disk member 131. Each of the metal joining materials has a through-hole formed therein at a position facing one of the holes in advance. Then, the feeding terminal 54 of the ceramic sintered compact 120 is inserted into the terminal hole intermediate portion 151b and the terminal hole lower portion 151c, and the ceramic sintered compact 120 is placed on the metal joining material disposed on the upper surface of the upper MMC disk member 131. As a result, a laminated body is obtained in which the lower MMC disk member 136, the metal joining material, the upper MMC disk member 131, the metal joining material, and the ceramic sintered compact 120 are sequentially stacked from the bottom. By heating and pressurizing the laminated body (TCB), a joined body 110 is obtained (FIG. 6F). In the joined body 110, the ceramic sintered compact 120 is joined to the upper surface of an MMC block 130, from which the cooling substrate 30 is to be produced, with the metal joining layer 40 therebetween. In the MMC block 130, the upper MMC disk member 131 is joined to the lower MMC disk member 136 with a metal joining layer 135 therebetween. The MMC block 130 includes the refrigerant flow path 32, the refrigerant supply path 36, the refrigerant discharge path 38, and the terminal hole 51. The terminal hole 51 is a hole having the terminal hole upper portion 151a, the terminal hole intermediate portion 151b, and the terminal hole lower portion 151c connected to each other.

The TCB is performed in the following manner, for example. That is, the laminated body is pressurized, and the members of the laminated body are joined together at a temperature lower than or equal to the solidus temperature of the metal joining material (for example, a temperature higher than or equal to a temperature obtained by subtracting 20° C. from the solidus temperature and lower than or equal to the solidus temperature). Thereafter, the temperature is returned to a room temperature. As a result, the metal joining material is turned into the metal joining layer 40. As the metal joining material at this time, an Al—Mg-based joining material or an Al—Si—Mg-based joining material can be used. For example, if the TCB is performed using an Al—Si—Mg-based joining material, the laminated body is heated and pressurized in a vacuum atmosphere. It is desirable to use a metal joining material having a thickness of about 100 μm.

Subsequently, the outer periphery of the ceramic sintered compact 120 is cut to form a step. Thereafter, a mask for forming the seal band 22b and the small protrusions 22c is attached to the upper surface of the ceramic sintered compact 120, blast media is ejected to perform blasting and, thereafter, the mask is removed. The small protrusions 22c are formed by blasting. As a result, the ceramic sintered compact 120 is turned into the ceramic substrate 20 having the central portion 22, the outer peripheral portion 24, and the wafer placement surface 22a. In addition, by cutting the outer periphery of the MMC block 130 to form a step, the cooling substrate 30 having the flange portion 34 is formed. Furthermore, the insulating tube 55 that allows the feeding terminal 54 inserted therethrough is disposed in a portion of the terminal hole 51 from the lower surface of the ceramic substrate 20 to the lower surface of the cooling substrate 30. Still furthermore, the insulating film 42 is formed by thermal spraying of ceramic powders to the side surface of the outer peripheral portion 24 of the ceramic substrate 20, the periphery of the metal joining layer 40, the periphery of the metal joining layer 40, and the side surface of the cooling substrate 30 (FIG. 6G). In this manner, the wafer placement table 10 is obtained.

Note that in FIG. 1, the cooling substrate 30 is described as an integral part. However, as illustrated in FIG. 6G, the cooling substrate 30 may have a structure in which two members are joined by a metal joining layer or a structure in which three or more members are joined by metal joining layers.

An example of usage of the wafer placement table 10 is described below with reference to FIG. 1. As described above, the wafer placement table 10 is fixed to the installation plate 96 of the chamber 94 using the clamp member 70. A shower head 98 is disposed on the ceiling surface of the chamber 94 to discharge process gas from a large number of gas injection holes into the inside of the chamber 94.

The focus ring 78 is placed on the FR placement surface 24a of the wafer placement table 10, and the disk-shaped wafer W is placed on the wafer placement surface 22a. The focus ring 78 has a step along the inner circumference of the upper end portion so as not to interfere with the wafer W. Under such a circumstance, the DC voltage of the wafer suction DC power supply 52 is applied to the wafer suction electrode 26 so that the wafer W is sucked to the wafer placement surface 22a. Then, the inside of the chamber 94 is set to have a predetermined vacuum atmosphere (or reduced pressure atmosphere), and the RF voltage is applied from the RF power supply 62 to the cooling substrate 30 while a process gas is being supplied from the shower head 98. Then, plasma is generated between the wafer W and the shower head 98. At this time, the plasma is used to perform CVD film formation or etching on the wafer W. Note that the focus ring 78 is also consumed as the wafer W is plasma-processed. However, since the focus ring 78 is thicker than the wafer W, the focus ring 78 is replaced after a plurality of wafers W are processed.

When processing the wafer W with high power plasma, it is necessary to efficiently cool the wafer W. In the wafer placement table 10, the metal joining layer 40 having a high thermal conductivity is used as a joining layer between the ceramic substrate 20 and the cooling substrate 30, instead of a resin layer having a low thermal conductivity. For this reason, the ability to draw heat from the wafer W (heat removal ability) is high. In addition, since the difference in thermal expansion between the ceramic substrate 20 and the cooling substrate 30 is small, no problem is likely to occur even if the stress relaxation property of the metal joining layer 40 is low. When the wafer placement table 10 is used, the refrigerant flows from the most upstream portion 32U toward the most downstream portion 32L of the refrigerant flow path 32 while drawing heat from the high temperature wafer W, so that the temperature of the refrigerant flowing through the refrigerant flow path 32 is higher in the most downstream portion 32L than in the most upstream portion 32U. However, the area ratio of the small protrusions 22c is higher in a portion other than the small region A1 than in the small region A1, which is the portion of the flow path overlapping range R10 facing the most upstream portion 32U. For this reason, the thermal resistance from the refrigerant flow path 32 to the wafer placement surface 22a is lower in each of the small regions A2 to An than in the small region A1. As a result, on the whole, the temperature difference can be reduced within the flow path overlapping range R10 of the wafer placement surface 22a. The flow velocity of the refrigerant flowing through the refrigerant flow path 32 is preferably 20 L/min to 40 L/min, more preferably 15 L/min to 35 L/min.

In the wafer placement table 10 according to the present embodiment described above, the area ratio of the small protrusions 22c in the flow path overlapping range R10 is minimized in the small region A1, which is the portion facing the most upstream portion 32U. When the wafer placement table 10 is used, the refrigerant flows from the upstream to the downstream of the refrigerant flow path 32 while drawing heat from the high temperature wafer W. For this reason, the temperature of the refrigerant flowing through the refrigerant flow path 32 is higher on the downstream side than on the upstream side. In addition, in the wafer placement table 10, the area ratio of the small protrusions 22c in the flow path overlapping range R10 is minimized in the small region Al facing the most upstream portion 32U. For this reason, in terms of the thermal resistance from the refrigerant flow path 32 to the wafer placement surface 22a, the thermal resistance is lower in a region other than the small region A1 (each of the small regions A2 to An) than in the small region A1. This is due to the following reason: The small protrusions 22c are made of ceramic, and ceramic has a higher thermal conductivity than the void. Therefore, in the portion where the area ratio of the small protrusions 22c is high, the proportion of the ceramic in the planar direction is higher than in the portion where the area ratio of the small protrusion 22c is not high and, thus, heat exchange between the wafer W and the refrigerant is promoted. As a result, removal of heat is promoted. As a result, on the whole, the temperature difference can be reduced within the flow path overlapping range R10 of the wafer placement surface 22a, which increases the thermal uniformity of the wafer W.

Furthermore, in the wafer placement table 10, the area ratio of the small protrusions 22c in the flow path overlapping range R10 gradually increases toward the downstream of the refrigerant flow path 32 from the small region A1. Therefore, the thermal uniformity of the wafer W increases more.

Still furthermore, in the wafer placement table 10, the area ratio of the small protrusions 22c in a portion facing a most downstream portion 32L within a range in which the refrigerant flow path 32 overlaps the wafer placement surface when the flow path overlapping range R10 is viewed in plan is greater than or equal to 150% of the area ratio of the small protrusions in the portion facing the most upstream portion. Therefore, the thermal uniformity of the wafer W is increased more.

Yet still furthermore, in the wafer placement table 10, the area ratio of the small protrusions 22c is higher in the adjacent region Qi adjacent to the small region Ai and outside the flow path overlapping range R10 than in the small region Ai of the flow path overlapping range R10. In general, heat is less likely to be removed from the adjacent region Qi than from the small region Ai of the flow path overlapping range R10. This is because the refrigerant flow path 32 is not located directly below the adjacent region Qi. In addition, the area ratio of the small protrusions 22c is higher in the adjacent region Qi than in the small region Ai of the flow path overlapping range R10. For this reason, heat removal from the adjacent region Qi is promoted. As a result, the thermal uniformity of the wafer W is increased more.

The wafer placement table 10 has the terminal hole 51 that penetrates the cooling substrate 30 in the vertical direction, and the cross-sectional area of the refrigerant flow path 32 is smaller in the surrounding region of the terminal hole 51 than in a region outside the surrounding region of the terminal hole 51. In the wafer placement surface 22a, the area ratio of the small protrusions 22c is higher in the directly above region R30 than in the surrounding region R40 outside the directly above region R30 of the terminal hole 51. In general, the directly above region R30 directly above the terminal hole 51 of the wafer W is likely to be a hot spot. However, the area ratio of the small protrusions 22c is higher in the directly above region R30 than in the surrounding region R40. For this reason, heat removal from the directly above region R30 is promoted. As a result, the thermal uniformity of the wafer W is increased more.

Furthermore, in the wafer placement table 10, the cooling substrate 30 is made of a metal matrix composite, and the ceramic substrate 20 and the cooling substrate 30 are joined by a metal joining layer 40. In a structure in which the cooling substrate 30 is a metal matrix composite and the joining layer is the metal joining layer 40, the thermal resistance from the refrigerant flow path 32 to the wafer placement surface 22a is low, so that the wafer temperature is easily influenced by the temperature gradient of the refrigerant. Therefore, it is highly effective to apply the present invention. In addition, since the metal joining layer 40 has a high thermal conductivity, it is suitable for heat removal. In addition, since the difference in thermal expansion between the ceramic substrate 20 and the cooling substrate 30 made of a metal matrix composite can be reduced, no problem is likely to occur even if the stress relaxation characteristic of the metal joining layer 40 is low.

Still furthermore, the refrigerant flow path 32 is formed in a zigzag pattern when the cooling substrate 30 is viewed in plan. Therefore, routing of the refrigerant flow path 32 all over the cooling substrate 30 is facilitated.

The present invention is not limited to the above-described embodiment and may be, of course, implemented in various modes within the technical scope of the present invention.

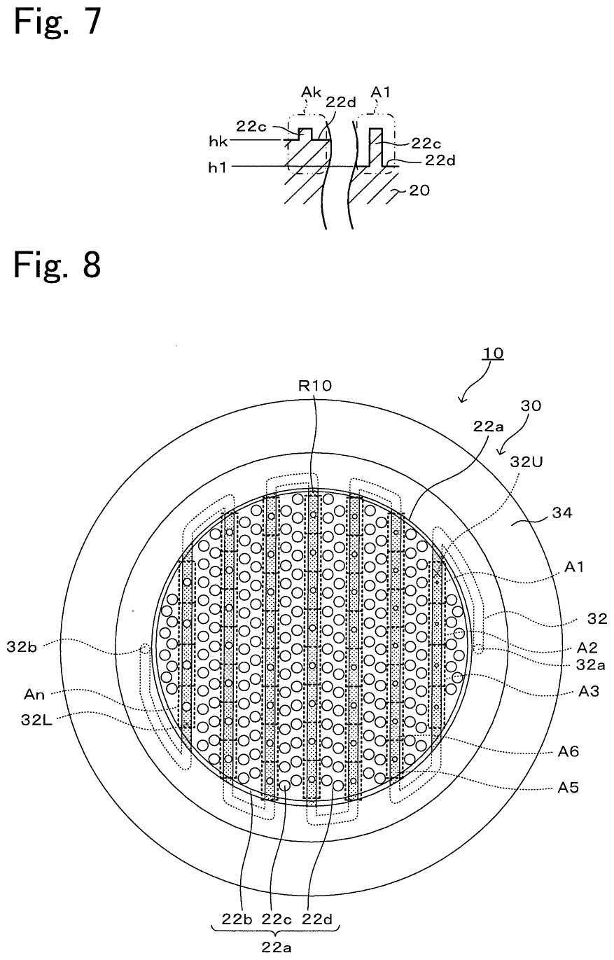

For example, according to the embodiment described above, in the flow path overlapping range R10, the area ratio of the small protrusion 22c in the small region A1, which is a portion facing the most upstream portion 32U, is set to be minimized. However, the area ratio is not limited thereto. For example, as illustrated in FIG. 7, a distance h1 from the top surface of the small protrusion 22c in the small region A1 to the reference plane 22d may be greater than a distance hk from the top surface of the small protrusion 22c in another small region Ak (k is an integer greater than or equal to 2 and less than or equal to n) to the reference plane 22d. In this case, the distance from the top surface of the small protrusion 22c to the reference plane 22d may be gradually decreased from the small region A1 toward the downstream of the refrigerant flow path 32. More specifically, when the relationship between the position of the flow path overlapping range R10 and the distance from the top surface of the small protrusion 22c to the reference plane 22d is represented by a graph, the distance from the small protrusion 22c to the reference plane 22d may be decreased continuously from the small region A1 toward the small region An or may be decreased in a stepwise manner. However, it is desirable that the distance be decreased continuously. In the case where the distance from the small protrusion 22c to the reference plane 22d is decreased continuously from the small region A1 toward the small region An, the distance may be decreased continuously at a constant slope, along a downward convex curve, or along an upward convex curve, for example. It is desirable that the distance from the small protrusion 22c to the reference plane 22d in the small region An facing the most downstream portion 32L be less than or equal to 80% of the distance from the small protrusion 22c to the reference plane 22d in the small region A1 facing the most upstream portion 32U.

According to the embodiment described above, the area ratio of the small protrusions 22c is changed by changing the array density of the small protrusions 22c. However, the present invention is not limited thereto. For example, as illustrated in FIG. 8, the area ratio of the small protrusion 22c may be changed by changing the area of the top surface of the small protrusion 22c. Alternatively, the area ratio of the small protrusions 22c may be changed by changing both the area of the top surface of the small protrusion 22c and the array density of the small protrusions 22c. Note that the same reference numerals are used in FIG. 8 to describe those constituent elements that are identical to the constituent elements of FIG. 2 without further description.

According to the embodiment described above, the area ratio of the small protrusions 22c is higher in the adjacent region Qi than in the small region Ai. However, the present invention is not limited thereto. For example, the distance from the top surface of the small protrusion 22c to the reference plane 22d may be less in the adjacent region Qi than in the small region Ai of the flow path overlapping range R10.

According to the embodiment described above, the area ratio of the small protrusions 22c is higher in the directly above region R30 than in the surrounding region R40. However, the present invention is not limited thereto. For example, the distance from the top surface of the small protrusion 22c to the reference plane 22d may be less in the directly above region R30 than in the surrounding region R40. In this case, it is desirable that the distance from the top surface of the small protrusion 22c to the reference plane 22d in the directly above region R30 be less than the distance from the top surface of the small protrusion 22c to the reference plane 22d in the surrounding region R40 by a distance L. The distance L is about 25% of the distance from the top surface of the small protrusion 22c to the reference plane 22d in the surrounding region R40.

According to the embodiment described above, in the flow path overlapping range R10, the area ratio of the small protrusion 22c in the small region A1 facing the most upstream portion 32U may be minimized, and the distance from the top surface of the small protrusion 22c to the reference plane 22d may be maximized. In addition, the area ratio of the small protrusions 22c may increase, and the distance from the top surface of the small protrusions 22c to the reference plane 22d may gradually decrease toward the downstream of the refrigerant flow path 32 from the small region A1 (toward the small region An from the small region A1). In this case, the area ratio of the small protrusion 22c in the small region An facing the most downstream portion 32L may be higher than or equal to 150% of the area ratio of the small protrusion 22c in the small region A1 facing the most upstream portion 32U. The distance from the top surface of the small protrusion 22c to the reference plane 22d in the small region An may be less than or equal to 80% of the distance from the top surface of the small protrusion 22c to the reference plane 22d in the small region A1. Furthermore, according to the embodiment described above, the area ratio of the small protrusion 22c may be higher in the adjacent region Qi than in the small region Ai, and the distance from the small protrusion 22c to the reference plane 22d may be less in the adjacent region Qi than in the small region Ai. Furthermore, according to the embodiment described above, the area ratio of the small protrusion 22c may be higher in the directly above region R30 than in the surrounding region R40, and the distance from the small protrusion 22c to the reference plane 22d may be less in the directly above region R30 than in the surrounding region R40.

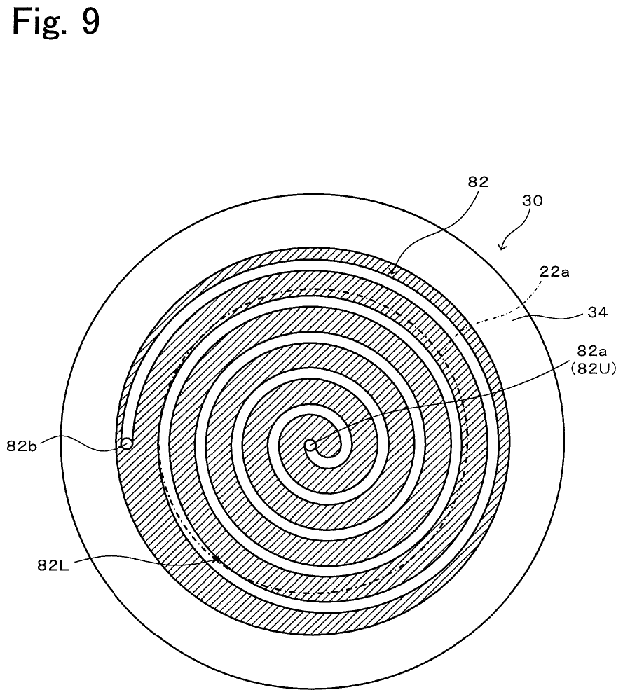

According to the embodiment described above, instead of the refrigerant flow path 32 having a zigzag pattern in plan view, a refrigerant flow path 82 having a spiral pattern in plan view may be adopted as illustrated in FIG. 9. The refrigerant flow path 82 is formed in a one-stroke pattern so as to spiral from an inlet 82a to an outlet 82b across the entire portion of the cooling substrate 30 excluding the flange portion 34. In this case, when a most upstream portion 82U and a most downstream portion 82L are defined in the region of the refrigerant flow path 82 that overlaps the wafer placement surface 22a in plan view, the most upstream portion 82U and the most downstream portion 82L are located as illustrated in FIG. 9. Note that the outer peripheral portion of the refrigerant flow path 82 may be used as the inlet, and the central portion may be used as the outlet.

According to the embodiment described above, the cooling substrate 30 is made of MMC. However, the cooling substrate 30 is not particularly limited thereto. The cooling substrate 30 may be made of a metal (for example, aluminum, titanium, molybdenum, tungsten, or an alloy thereof).

According to the embodiment described above, the ceramic substrate 20 and the cooling substrate 30 are joined by the metal joining layer 40. However, the present invention is not particularly limited thereto. For example, a resin joining layer may be used instead of the metal joining layer 40.

According to the embodiment described above, the wafer suction electrode 26 is built in the central portion 22 of the ceramic substrate 20. However, instead of or in addition to the configuration, an RF electrode for plasma generation or a heater electrode (a resistance heating element) may be built in the ceramic substrate 20. In addition, a focus ring (FR) suction electrode may be built in the outer peripheral portion 24 of the ceramic substrate 20, or an RF electrode or a heater electrode may be built in the outer peripheral portion 24.

According to the embodiment described above, the wafer placement table 10 may have a plurality of holes that penetrate the wafer placement table 10 in the vertical direction. The holes include a plurality of gas holes that are open in the wafer placement surface 22a and a lift pin hole that allows a lift pin to be inserted therein. The lift pin is used to move the wafer W up and down with respect to the wafer placement surface 22a. The plurality of gas holes are provided at appropriate positions in the wafer placement surface 22a in plan view. A heat conductive gas, such as He gas, is supplied to the gas holes. Normally, the gas hole is provided so as to be open in a portion of the wafer placement surface 22a having the seal band 22b and the small protrusions 22c while avoiding the seal band 22b and the small protrusion 22c. When heat conductive gas is supplied to the gas holes, the space on the back surface side of the wafer W placed on the wafer placement surface 22a is filled with the heat conductive gas. A plurality of lift pin holes are provided at equal intervals along the concentric circles on the wafer placement surface 22a when the wafer placement surface 22a is viewed in plan. When the wafer placement table 10 has a gas hole or a lift pin hole, the area ratio of the small protrusions 22c may be higher in the directly above region R30 than in the surrounding region R40 outside the directly above region R30, as illustrated in FIG. 5. Alternatively, the distance from the top surface of the small protrusion 22c to the reference plane 22d may be less in the area directly above R30 than in the surrounding region R40 located outside the directly above region R30. Still alternatively, the area ratio of the small protrusions 22c may be higher in the directly above region R30 than in the surrounding region R40 outside the directly above region R30, and the distance from the top surface of the small protrusion 22c to the reference plane 22d may be less in the directly above region R30 than in the surrounding region R40. In this manner, the thermal uniformity of the wafer W is improved more.

According to the embodiment described above, the ceramic sintered compact 120 illustrated in FIG. 6A is produced by hot-press firing a molded body of ceramic powders. At this time, the molded body may be produced by stacking a plurality of tape molded bodies. The body may be produced by a mold casting technique, or the body may be produced by compacting ceramic powders.

According to the embodiment described above, the flow path overlapping range R10 is divided into n small regions A1 to An each having the same area. At this time, it is desirable that n be greater than or equal to 5.

According to the embodiment described above, the flow path overlapping range R10 is divided into a plurality of portions in the middle. However, the present invention is not limited thereto. For example, the flow path overlapping range R10 does not necessarily have to be divided in the middle.

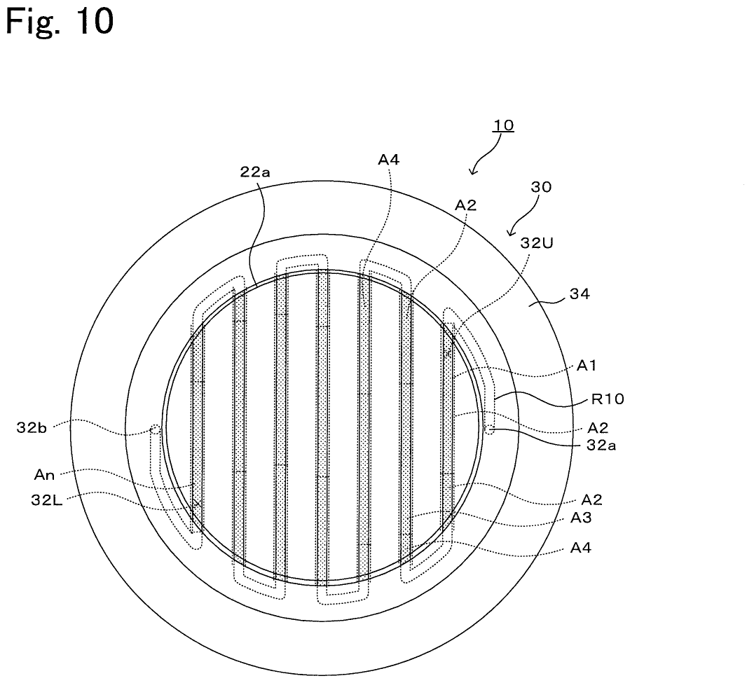

According to the embodiment described above, the small region Ak may consist of one continuous region or two or more divided regions (for example, the small region A2 and the small region A4) as illustrated in FIG. 10. Note that in FIG. 10, the small protrusions 22c are not illustrated. In addition, the same reference numerals are used in FIG. 10 to describe those constituent elements that are identical to the constituent elements of FIG. 2 without further description.

The present application claims priority from Japanese Patent Application No. 2021-192899, filed on Nov. 29, 2021, the entire contents of which are incorporated herein by reference.

What is claimed is:

1. A wafer placement table comprising:
a ceramic substrate having an upper surface serving as a wafer placement surface that allows a wafer to be placed thereon, the ceramic substrate having a built-in electrode;
a cooling substrate including a refrigerant flow path;
a joining layer configured to join the ceramic substrate to the cooling substrate; and
a plurality of small protrusions disposed on a reference plane of the wafer placement surface, top surfaces of the small protrusions being able to support a lower surface of the wafer,
wherein the top surfaces of all the small protrusions are located on the same plane, and
wherein in a flow path overlapping range of the wafer placement surface in which the wafer placement surface overlaps the refrigerant flow path in plan view, an area ratio of the small protrusions is minimized in a portion facing a most upstream portion of the refrigerant flow path within a range in which the refrigerant flow path overlaps the wafer placement surface in plan view.

2. The wafer placement table according to claim 1, wherein the area ratio of the small protrusions in the flow path overlapping range gradually increases toward a downstream of the refrigerant flow path from the portion facing the most upstream portion.

3. The wafer placement table according to claim 1, wherein in the flow path overlapping range, the area ratio of the small protrusions in a portion facing a most downstream portion of the refrigerant flow path within a range in which the refrigerant flow path overlaps the wafer placement surface in plan view is greater than or equal to 150% of the area ratio of the small protrusions in the portion facing the most upstream portion.

4. The wafer placement table according to claim 1, wherein in terms of a predetermined region in the flow path overlapping range, the area ratio of the small protrusions is higher in an adjacent region adjacent to the predetermined region and outside the flow path overlapping range than in the predetermined region.

5. The wafer placement table according to claim 1, comprising:
a hole configured to penetrate the cooling substrate in the vertical direction,
wherein a cross-sectional area of the refrigerant flow path is less in a surrounding region of the hole than in a region outside the surrounding region of the hole, and
wherein the area ratio of the small protrusions is higher in a directly above region of the wafer placement surface that is located directly above the hole than in a region outside the directly above region.

6. A wafer placement table comprising:
a ceramic substrate having an upper surface serving as a wafer placement surface that allows a wafer to be placed thereon, the ceramic substrate having a built-in electrode;
a cooling substrate including a refrigerant flow path;
a joining layer configured to join the ceramic substrate to the cooling substrate; and
a plurality of small protrusions disposed on a reference plane of the wafer placement surface, top surfaces of the small protrusions being able to support a lower surface of the wafer,
wherein the top surfaces of all the small protrusions are located on the same plane, and
wherein in a flow path overlapping range of the wafer placement surface in which the wafer placement surface overlaps the refrigerant flow path in plan view, a distance from the top surface of the small protrusion to the reference plane is maximized in a portion facing a most upstream portion of the refrigerant flow path within a range in which the refrigerant flow path overlaps the wafer placement surface in plan view.

7. The wafer placement table according to claim 6, wherein the distance from the top surface of the small protrusion to the reference plane in the flow path overlapping range gradually decreases toward a downstream of the refrigerant flow path from the portion facing the most upstream portion.

8. The wafer placement table according to claim 6, wherein in the flow path overlapping range, the distance from the top surface of the small protrusion to the reference plane in a portion facing the most downstream portion of the refrigerant flow path within a range in which the refrigerant flow path overlaps the wafer placement surface in plan view is less than or equal to 80% of the distance from the top surface of the small protrusion to the reference plane in the portion facing the most upstream portion.

9. The wafer placement table according to claim 6, wherein in terms of a predetermined region in the flow path overlapping range, the distance from the top surface of the small protrusion to the reference plane is less in an adjacent region adjacent to the predetermined region and outside the flow path overlapping range than in the predetermined region.

10. The wafer placement table according to claim 6, comprising:
a hole configured to penetrate the cooling substrate in the vertical direction,
wherein a cross-sectional area of the refrigerant flow path is less in a surrounding region of the hole than in a region outside the surrounding region of the hole, and
wherein the distance from the top surface of the small protrusion to the reference plane is less in a directly above region of the wafer placement surface that is located directly above the hole than in a region outside the directly above region.

11. The wafer placement table according to claim 1, wherein the cooling substrate is made of a metal matrix composite, and
wherein the joining layer is a metal joining layer.

12. The wafer placement table according to claim 6, wherein the cooling substrate is made of a metal matrix composite, and
wherein the joining layer is a metal joining layer.
